(19) United States
(12) Patent Application Publication
(10) Pub. No.: US 2026/0324115 A1
(43) Pub. Date: Oct. 15, 2026

(54) PHOTODETECTOR, DETECTION DEVICE, AND FABRICATING METHOD THEREOF

(71) Applicant: National Taiwan University, Taipei (TW)

(72) Inventors: Ching-Fuh Lin, Taipei (TW); Ting-Kai Chang, Taipei (TW)

(21) Appl. No.: 19/635,272

(22) Filed: Mar. 31, 2026

(30) Foreign Application Priority Data
Apr. 14, 2025 (TW) 114113960

(51) Int. Cl. H10F 39/00; G01J 5/00; G01J 5/10; G01N 21/3504; G01N 21/359

(52) U.S. Cl. CPC H10F 39/8067; G01J 5/10; G01N 21/3504; H10F 39/8063; G01J 2005/0077; G01N 21/359

(57) ABSTRACT

A photodetector includes a semiconductor substrate, a metal layer, a first electrode, and a second electrode. The surface of the semiconductor substrate is etched to from a composite structure array. The semiconductor substrate forms a Schottky contact with the metal layer. The first electrode contacts an upper surface of the metal layer, and the second electrode forms ohmic contact with a lower surface of the semiconductor substrate. Each composite structure includes a cavity to trap an incident light for inducing surface resonance and a center core structure within the cavity to gather electric field.

### CROSS-REFERENCE TO RELATED APPLICATIONS

The entire contents of Taiwan Patent Application No. 114113960, filed on Apr. 14, 2025, from which this application claims priority, are expressly incorporated herein by reference.

### BACKGROUND OF THE INVENTION

### 1. Field of the Invention

The present invention generally relates to a photodetector, a detection device, and their fabrication method.

### 2. Description of Related Art

Current infrared sensors mostly use semiconductors with small energy gaps such as III-V or Ge as the active layer or detection-absorbing material to detect infrared light with a small photon energy. Although existing III-V or Ge detectors have been well-established in their manufacturing process, these materials are more expensive than others, and the process requires many complex and expensive epitaxial equipment. The principle of such sensors is mostly mid band-gap absorption (MBA). Carriers in the semiconductor are excited by incident light and cross the semiconductor bandgap to generate photocurrents. To improve the detection efficiency or the responsivity, such sensors require incorporating complex multiple quantum wells (MQWs) or multiple quantum dots (MQDs) in the active layer. In view of the above reasons, such infrared light detectors are still not widely used.

Taiwan Pat. No. TWI686936B to Lin et al. discloses a photodetector with a metal/semiconductor junction that employs a different mechanism to detect infrared light and feature in fabrication and low cost. An inverted or upright pyramid array is fabricated on the surface of the semiconductor to induce surface plasmon resonance, confining the incident light within the microstructure. The gradient widths of the pyramid structure allow wavelengths of incident light to generate a larger response through the mechanism, resulting in improved performance not only in the visible light but also in the near-infrared band.

Taiwan Pat. No. TWI806274B to Lin et al. discloses a photodetector, in which pre-treatment and/or post-treatment, including an insulating layer between the metal and semiconductor is used to improve signal-to-noise ratio (SNR). The fabricated photodetector has a response time of less than 10 microseconds.

Taiwan Pat. No. TWI886519B to Lin et al. discloses a light absorption structure and a photodetector including the light absorption structure. The light absorption structure an inverted truncated-pyramid structure (ITPS) array to absorb incident light, particularly in the infrared band. The inverted trapezoidal structures are made of a metal layer, and the cross-section of each inverted truncated-pyramid structure includes an upper base and a lower base, where the length of the upper base is greater than the length of the lower base. The trapezoidal structures increase the response in a specific incident light band.

### SUMMARY OF THE INVENTION

This summary is provided to introduce a selection of concepts in a simplified form that are further described below in the detailed description. This summary, and the foregoing background, is not intended to identify key aspects or essential aspects of the claimed subject matter. Moreover, this summary is not intended for use as an aid in determining the scope of the claimed subject matter.

In one aspect, a photodetector is provided with a semiconductor substrate, a metal layer, a first electrode, and a second electrode. The semiconductor substrate has a composite structure array composed of composite structures. The metal layer forms a Schottky contact with a surface of the composite structure array. The first electrode is in contact with an upper surface of the metal layer. The second electrode is in an ohmic contact with a lower surface of the semiconductor substrate. Each composite structure includes a resonant cavity allowing for an incident light inducing resonance therein and a center core structure protruded from a central bottom of the resonant cavity for collecting resonant energy.

In some embodiments, the resonant cavity is inverted pyramid-shaped, inverted trapezoid-shaped, cuboid-shaped, or cup-shaped.

In some embodiments, the center core structure is upright pyramid-shaped, cylinder-shaped, cuboid-shaped, trapezoid-shaped, or cone-shaped.

In some embodiments, the photodetector is used to detect the incident light with wavelengths greater than 1.1 μm.

In some embodiments, the responsivity of the photodetector is equal to or greater than 0.557 V/W for the incident light at wavelength of 3.46 μm.

In some embodiments, the first electrode is fence-shaped.

In some embodiments, the first electrode is mesh-shaped.

In some embodiments, the metal layer is conformally deposited on the surface of the composite structure array.

In some embodiments, the thickness of the metal layer is approximately 10 nm.

In another aspect, a method for fabricating a photodetector is provided with the steps of: providing a semiconductor substrate; depositing a shielding layer on an upper surface of the semiconductor substrate; depositing a photoresist layer over the shielding layer that is deposited on the upper surface of the semiconductor substrate; exposing and developing the photoresist layer with a photomask to obtain a patterned photoresist layer, wherein the photomask comprises an array of light-blocking patterns, and wherein each of the light-blocking patterns comprises a light-transmitting core portion, or each of the light-blocking patterns comprises an outer pattern and a light-blocking core pattern within the outer pattern; etching the shielding layer and the patterned photoresist layer to obtain a patterned shielding layer; etching the semiconductor substrate to form a composite structure array, wherein the composite structure array comprises a plurality of composite structures, and each of the plurality of composite structures comprises a resonant cavity allowing for an incident light inducing resonance therein and a center core structure protruded from a central bottom of the resonant cavity for collecting resonant energy; depositing a metal layer on a surface of the plurality of composite structures; depositing a first electrode on the metal layer; and depositing a second electrode on a lower surface of the semiconductor substrate.

In some embodiments, the metal layer is conformally formed on the surface of the plurality of composite structures.

In another aspect, a detection device is provided with an array of the photodetectors.

Compared to previous photodetectors and photodetector arrays, the proposed photodetectors and photodetector arrays exhibit higher responsivity in the infrared band. This is particularly advantageous for instantaneous infrared light detection. Furthermore, the proposed photodetectors and photodetector arrays also offer advantages such as low manufacturing cost, mass production capability, and ease of integration with silicon-based processes.

### BRIEF DESCRIPTION OF THE DRAWINGS

Non-limiting and non-exhaustive embodiments of the disclosed technology, including the preferred embodiment, are described with reference to the following figures, wherein like reference numerals refer to like parts throughout the various views unless otherwise specified.

FIG. 1 shows a photodetector in accordance with an embodiment of the present invention.

FIG. 2A shows a WPS array formed on the surface of a semiconductor in accordance with an embodiment of the present invention.

FIG. 2B shows a method of fabricating a fence-shaped electrode according to an embodiment of the present invention.

FIG. 3 shows a measurement system used for experiments of the present invention.

FIG. 4 shows a light field simulation of the photodetector 1 shown in FIG. 1.

FIG. 5 are top-view (1500×) and side-view (2500×) scanning electron microscope (SEM) images of a W-shaped composite pyramid structure array fabricated according to an embodiment of the present invention.

FIG. 6 shows relationship between incident light wavelength and responsivity of an inventive photodetector with a W-shaped composite pyramid structure (WPS) array formed on silicon surface with a period of 16 μm and a comparison photodetector with an inverted pyramid structure array formed on silicon surface with a period of 16 μm.

FIGS. 7A, 7B, and 7C are light field simulations of composite structures respectively having only inverted pyramid, cubic, and cylindrical resonant cavities according to some embodiments of the present invention.

FIG. 8A shows light field simulation of a composite structure including a cylindrical resonant cavity and a cylindrical center core structure in accordance with an embodiment of the present invention.

FIG. 8B shows light field simulation of a composite structure including a cubic resonant cavity and a cubic center core structure in accordance with an embodiment of the present invention. FIG. 8C shows light field simulation of a composite structure including a cubic resonant cavity and a cubic center core structure in accordance with an embodiment of the present invention, wherein the height of the cubic center core structure is greater than the height of the cubic resonant cavity.

FIG. 9A shows light field simulation of a composite structure having only an inverted trapezoid cavity in accordance with an embodiment of the present invention.

FIG. 9B shows light field simulation of a composite structure having an inverted trapezoidal resonant cavity and a trapezoidal center core structure in accordance with an embodiment of the present invention.

FIG. 10A shows line graphs of incident light wavelength versus integrated electric field for composite structure containing only cup-shaped, cube-shaped, trapezoidal, and inverted pyramid resonant cavity.

FIG. 10B shows line graphs of incident light wavelength versus integrated electric field for composite structure containing cube-shaped resonant cavity and cube-shaped central core structures (CUB_CUB), inverted trapezoidal resonant cavity and trapezoidal central core structures (TRP_TRP), cylindrical resonant cavity and cylindrical central core structures (CIR_CIR), and inverted trapezoidal resonant cavity and upright pyramid central core structures (TRP_PS), respectively.

FIG. 10C shows a line graph of incident light wavelength versus integrated electric field for composite structure containing only inverted pyramid resonant cavity.

FIG. 10D shows a line graph of incident light wavelength and integrated electric field for composite structure containing an inverted trapezoidal resonant cavity and an upright pyramidal central core structure.

FIGS. 11A and 11B are perspective view and cross-sectional view, respectively, showing an example of fabricating an inverted pyramidal structure array in accordance with an embodiment of the present invention.

FIG. 12 is an SEM image showing a photomask used in FIGS. 11A and 11B.

FIG. 13 is a cross-sectional view showing an example of fabricating a composite structure array in accordance with an embodiment of the present invention.

FIG. 14 is an SEM image showing a photomask used in FIG. 13.

### DETAILED DESCRIPTION OF THE PREFERRED EMBODIMENT

Embodiments are described more fully below with reference to the accompanying Figures, which form a part hereof and show, by way of illustration, specific exemplary embodiments. These embodiments are disclosed in sufficient detail to enable those skilled in the art to practice the invention. However, embodiments may be implemented in many different forms and should not be construed as being limited to the embodiments set forth herein. The following detailed description is, therefore, not to be taken in a limiting sense.

TW Pat. Nos. TWI686936B, TWI806274B, and No. TWI886519B have disclosed photodetectors with planar, inverted pyramid array, upright pyramid array, and inverted trapezoidal structure arrays formed on surface of semiconductor substrate. Those photodetectors exhibit fine responses in the visible light and near-infrared light band. The entire contents of all published documents discussed are fully incorporated by reference as if fully set forth herein.

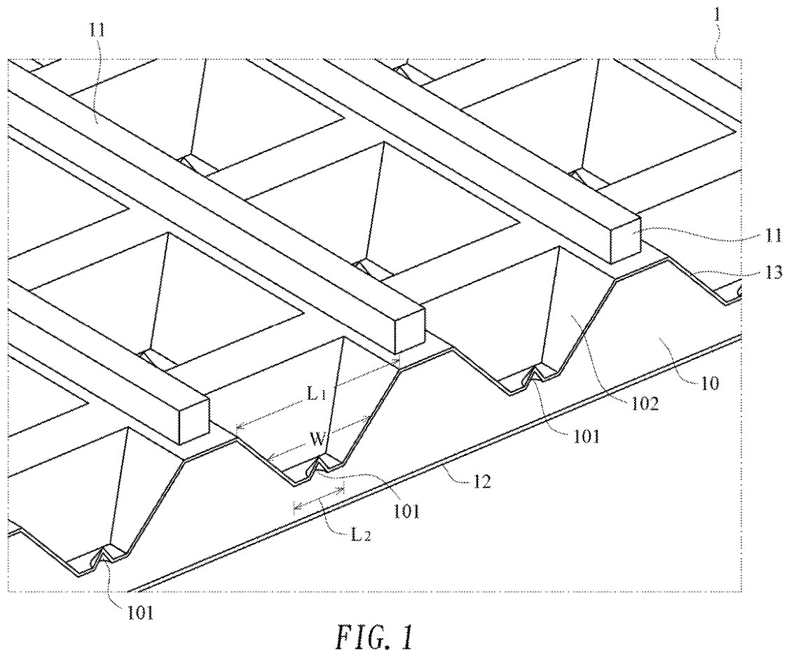

FIG. 1 shows a photodetector 1 according to an embodiment of the present invention. Referring to FIG. 1, the photodetector generally includes a semiconductor substrate 10, a metal layer 13, a first electrode 11, and a second electrode 12. A composite structure array is formed on the surface of the semiconductor substrate 10 with a suitable manner, such as, but not limited to, dry etching and/or wet etching. Each composite structure includes a resonant cavity 102 in which incident light induces local surface plasmon resonance (LSPR), and a center core structure 101 located within the resonant cavity 101 for collecting resonant energy. Typically, the center core structure 101 is protruded from the center of the bottom of the resonant cavity 102.

In some embodiments, the resonant cavity 102 may be, but is not limited to, inverted pyramid-shaped, inverted trapezoid-shaped, cube-shaped (including rectangular cuboid-shaped), or cup-shaped.

In some embodiments, the center core structure 101 may be, but is not limited to, upright pyramid-shaped, cylinder-shaped, cube-shaped (including rectangular cuboid-shaped), or cone-shaped.

Referring to FIG. 1, for illustration purposes, an exemplary W-shaped composite structure array is provided with each composite structure consisting of a trapezoidal resonant cavity 102 and an upright pyramid-shaped center core structure 101. The cross-section of each W-shaped composite pyramid structure includes an upper base and a lower base, with dimensions (lengths) L1 and L2, respectively, where L1 is greater than L2, and an upright pyramid is protruded from the central region of the lower base. Furthermore, the width W of the resonant cavity 102 gradually increases from L2 to L1, corresponding to different wavelengths of incident light for inducing local surface plasmon resonance (LSPR) in different regions of the resonant cavity 102. At least a portion of the surface of the metal layer 13 forms Schottky contact with the surface of the W-shaped composite pyramid structure array. Preferably, the metal layer 13 is conformally formed on the composite structure array. The first electrode 11 may contact an upper surface of the metal layer 13. The second electrode 12 may form ohmic contact with a back surface of the semiconductor substrate 10. Carriers in the metal layer 13 or semiconductor substrate 10 are excited by incident photons to form hot carriers that cross the interface between the metal and semiconductor substrate, thus generating a photocurrent. Notice that it is not necessary to have a first electrode 11 above every two adjacent W-shaped composite pyramid structures. That is, the spacing between two interconnected electrode patterns can be larger. In the illustrated embodiment, the first electrode 11 is fence-shaped. In other embodiments, the first electrode 11 can also be finger-shaped or mesh-shaped.

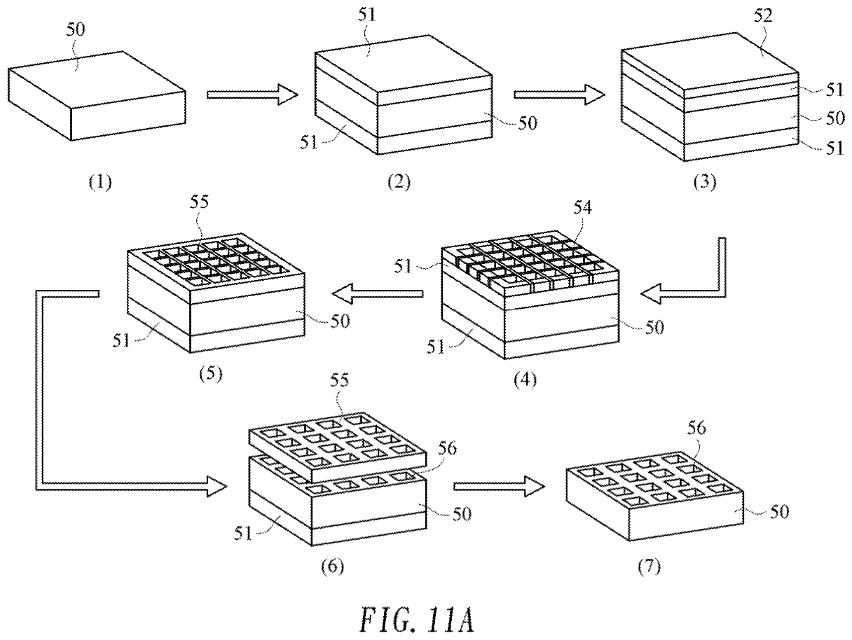

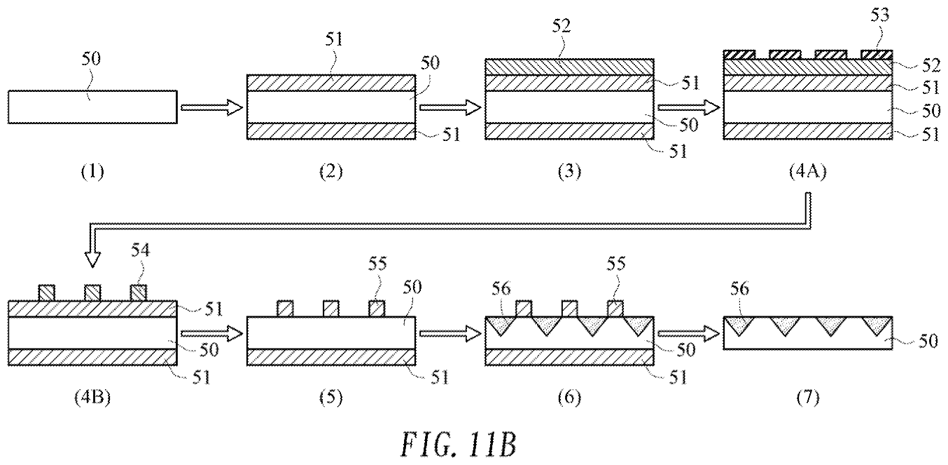

FIGS. 11A and 11B are perspective view and cross-sectional view, respectively, showing an example of fabricating an inverted pyramidal structure array in accordance with an embodiment of the present invention, in which step (4) of FIG. 11A corresponds to steps (4A) and (4B) of FIG. 11B. In the exemplary example, the semiconductor substrate is a silicon substrate, and the metal layer is silver layer. Referring to step (1) of FIGS. 11A and 11B, a silicon wafer is cut into a silicon substrate 50 with a size of 2.5×2.5 cm by a laser cutter. The silicon substrate 50 is then subjected to an ultrasonic cleaner for 10 minutes each, sequentially with IPA, acetone, IPA, and methanol, to remove organic matter and dust from its surface.

Referring to Step (2) of FIGS. 11A and 11B, a 600 nm shielding layer 51, such as SiO₂, is deposited on both top and bottom surfaces of the silicon substrate 50 using a plasma-enhanced chemical vapor deposition (PECVD) system. In Step (3), by using a spin coater, hexamethyldisilazane (HMDS) is coated onto the surface of the upper shielding layer 51 with an initial speed of 1000 rpm for 10 seconds and an eventual speed of 4000 rpm for 40 seconds. And then a photoresist layer 52, such as ENPI-307 negative photoresist, is spin coated onto the HMDS surface at a speed of 8000 rpm for 10 seconds. Next, soft-bake the spin-coated silicon substrate 50 using a hot plate with temperature of 110 °C for 3 minutes.

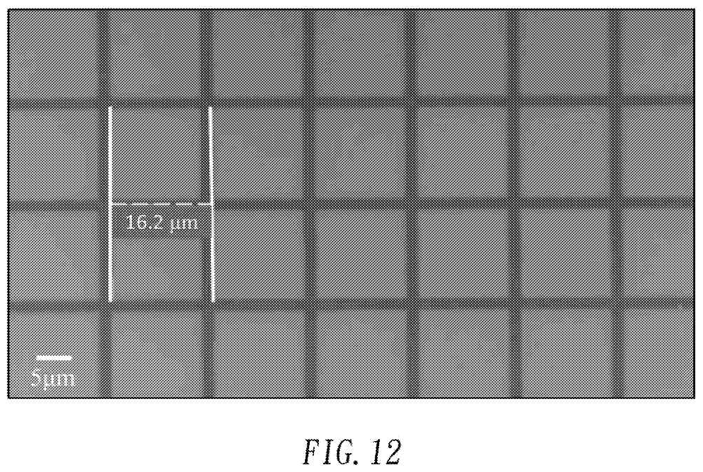

Referring to Step (4A), exposes the sample of step (3) by using photomask 53 with square patterns as shown in FIG. 12 for approximately 20 seconds, then bake the sample at 130 °C for 2 minutes. Step (4B) is to develop the sample with MF-319 developer for about 40 seconds to obtain a patterned photoresist layer 54 with a square pattern array removed. After confirming the square pattern with an optical microscope (OM), the sample is then baked at 130 °C for 3 minutes. The yellowish areas in the microscope image of FIG. 12 contain metal (e.g., chromium, and in another example, the darker areas of FIG. 12 instead contain metal and a positive photoresist is used.

Referring to Step (5) of FIGS. 11A and 11B, the patterned photoresist layer 54 and the upper shielding layer 51 are etched using reactive ion etching (RIE) to obtain a patterned shielding layer 55. Gas CHF₃ is used for dry etching the shielding layer 51 (SiO₂) with controlled flow rate of 30 sccm, pressure of 1.30 Pa, and RF power of 90 W, for 40 minutes. Gas O₂ is used for etching the patterned photoresist layer 54 with controlled flow rate of 50 sccm, pressure of 13.30 Pa, and RF power of 100 W, for 10 minutes.

Referring to Step (6) of FIGS. 11A and 11B, the sample is then wet-etched for 7 minutes with KOH at a concentration of 45 wt % to produce an inverted pyramid structure (IPS) array 56 at the surface of the silicon substrate 50.

Referring to Step (7) of FIGS. 11A and 11B, in a cleanroom, immerse the silicon substrate 50 in BOE etching solution for approximately 10 minutes to remove residual SiO₂ layer from the upper and lower surfaces. Finally, clean the sample with deionized water and dry it with a nitrogen gun.

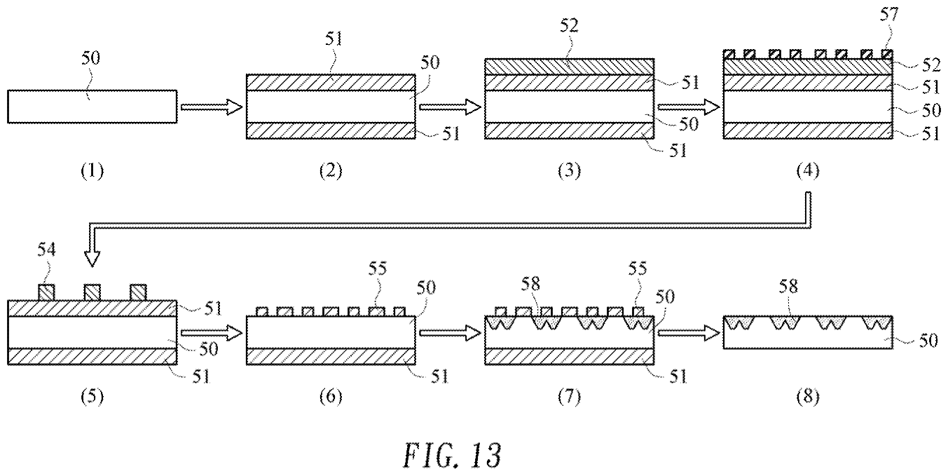

FIG. 13 is a cross-sectional view showing a method for fabricating of a W-shaped composite pyramid structure (WPS) array according to an embodiment of the present invention, wherein the semiconductor substrate is an n-type silicon substrate, and the metal layer is silver layer.

Referring to step (1) of FIG. 13, a silicon wafer is cut into a silicon substrate 50 with a size of 2.5×2.5 cm by a laser cutter. The silicon substrate 50 is then subjected to an ultrasonic cleaner for 10 minutes each, sequentially with IPA, acetone, IPA, and methanol, to remove organic matter and dust from its surface.

Referring to Step (2) of FIG. 13, a 600 nm shielding layer 51, such as SiO₂, is deposited on both top and bottom surfaces of the silicon substrate 50 using a plasma-enhanced chemical vapor deposition (PECVD) system.

Referring to Step (3) of FIG. 13, by using a spin coater, hexamethyldisilazane (HMDS) is coated onto the surface of the upper shielding layer 51 with an initial speed of 1000 rpm for 10 seconds and an eventual speed of 4000 rpm for 40 seconds. And then a photoresist layer 52, such as ENPI-307 negative photoresist, is spin coated onto the HMDS surface at a speed of 8000 rpm for 10 seconds. Next, soft-bake the spin-coated silicon substrate 50 using a hot plate with temperature of 110 °C for 3 minutes.

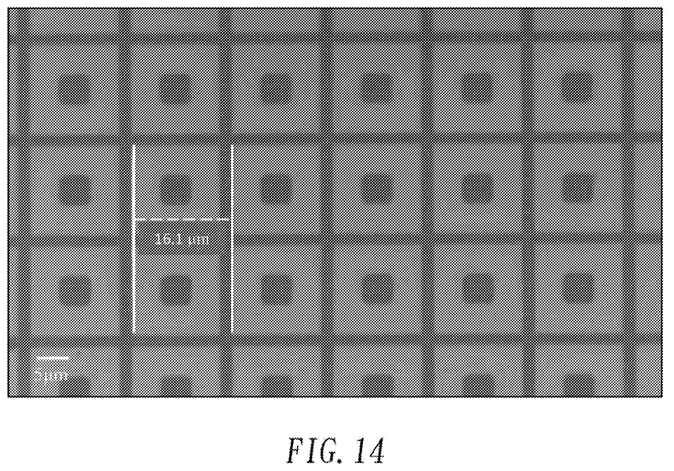

Referring to Step (4) of FIG. 13, exposes the sample of step (3) by using photomask 57 with concentric-square patterns (a square within a square) as shown in FIG. 14 for approximately 33 seconds, then bake the sample at 130 °C for 2 minutes. The yellowish areas in the microscope image of FIG. 14 contain light-blocking material such as metal (e.g., chromium), and in another example, the darker areas of FIG. 14 instead contain the light-blocking material (e.g., metal) and a positive photoresist is used. The photomask has an array of light-blocking patterns, each containing a light-transmitting core portion. Alternatively, each light-blocking pattern includes an outer pattern and a core pattern within that outer pattern. In the exemplary example a negative photoresist used, the square outer pattern contains a light-transmitting square core portion. If a positive photoresist is used, the square outer pattern contains a square light-blocking core pattern within the square outer pattern. The composite structure array may be fabricated using a photomask in which the outer pattern and light-transmitting core portion or light-blocking core pattern have other shapes, such as circles, polygons, etc.

Referring to Step (5) of FIG. 13, next, develop the sample with MF-319 developer for approximately 55 seconds to obtain a patterned photoresist layer 54, e.g., a patterned photoresist layer with concentric-square patterns. After confirming the concentric-square patterns with an optical microscope (OM), the sample is then hard-baked at 130 °C for 3 minutes.

Referring to Step (6) of FIG. 13, the patterned photoresist layer 54 and the upper shielding layer 51 are etched using reactive ion etching (RIE) to obtain a patterned shielding layer 55. Gas CHF₃ is used for dry etching the shielding layer 51 (SiO₂) with controlled flow rate of 30 sccm, pressure of 1.30 Pa, and RF power of 90 W, for 45 minutes. Gas O₂ is used for etching the patterned photoresist layer 54 with controlled flow rate of 50 sccm, pressure of 13.30 Pa, and RF power of 100 W, for 15 minutes.

Referring to Step (7) of FIG. 13, the sample is then wet-etched with a 45 wt % KOH solution to produce a composite pyramid structure 58 (WPS) array at the surface of the silicon substrate 50. Referring to Step (8) of FIG. 13, in a cleanroom, the silicon substrate is immersed in BOE etching solution to remove SiO₂ from its surface. The silicon substrate is then cleaned with deionized water and dried with a nitrogen gun.

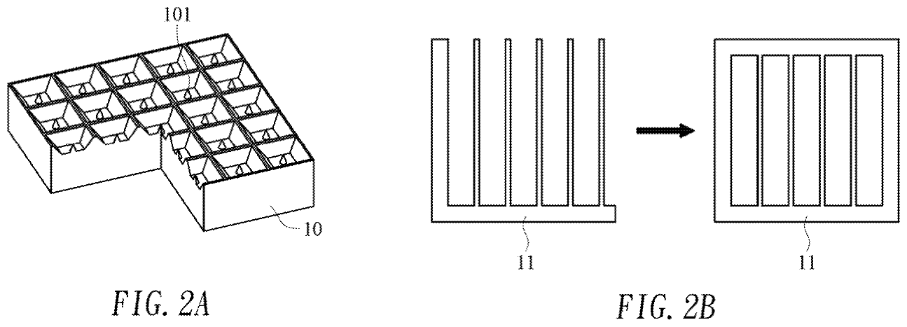

Continuing from the structure in step (8) of FIG. 13, a metal layer (active layer), a first electrode, and a second electrode (back electrode) may then be fabricated by vapor deposition. For example, a 100 nm thick aluminum layer is deposited on the bottom surface of the silicon substrate at a deposition rate of 1 Å/s as the back electrode. A 10 nm thick silver layer is conformally deposited on the surface of the WPS structure array at a deposition rate of 0.1 Å/s. Next, a 200 nm thick Ag fence-shaped electrode is fabricated. As shown in step (1) of FIG. 2B, a finger-shaped mask is placed above the sample to deposit 10 nm-thick silver layer with deposition rates of 0.1 Å/s, 0.3 Å/s, and 0.5 Å/s, respectively, and eventually 70 nm-thick silver layer is then deposited at 1 Å/s to form a finger-shaped electrode. As shown in step (2) of FIG. 2B, the finger-shaped electrode is then rotated 180° and the step (1) is repeated to deposit 10 nm-thick silver layer at 0.1 Å/s, 0.3 Å/s, and 0.5 Å/s, respectively, and eventually 70 nm-thick silver at 1 Å/s, thus forming the fence-shape electrode with a total thickness of 200 nm.

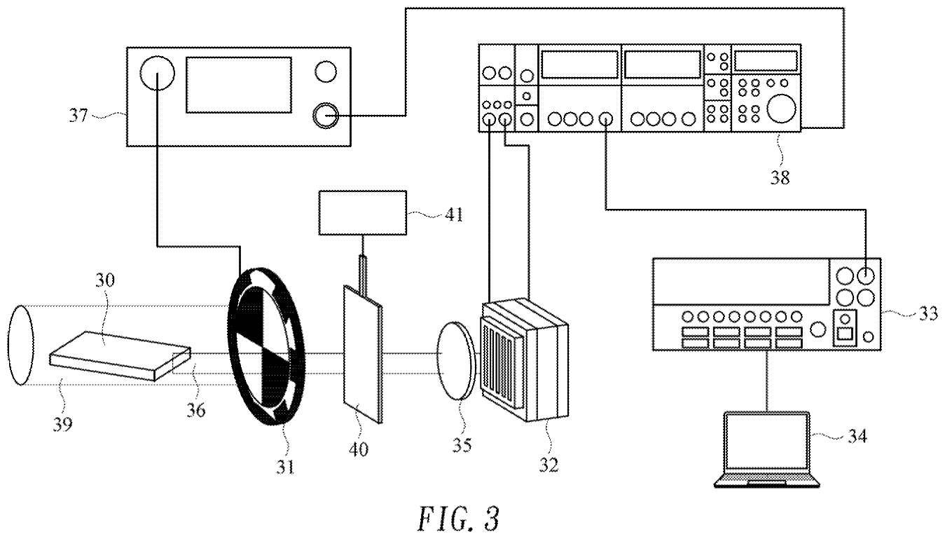

FIG. 3 shows a measurement system used for the present invention. Referring to FIG. 3, the measurement system includes a light source 30, a (fast) chopper 31, a device under test (DUT) 32, a power meter 33 (Keithley 2400), a computer 34, a controller 37, a lock-in amplifier 38, and a reflector 39. DUT 32 may be the photodetector 10 shown in FIG. 1. To measure V-T plot, a ceramic heater is used as the light source 30 and heated to 300 °C to generate blackbody radiation. A slow chopper 40 is connected to controller 41 (Arduino, model Leonardo). Through controller 41, the slow chopper 40 is switched ON and OFF periodically, e.g., 5 -15 seconds ON and 5 -15 seconds OFF, to pass through or block the light 36, and thus a signal with an ON-OFF period of 10-30 seconds generates. Controller 37 connects to fast chopper 31 and lock-in amplifier 38. Through controller 37, the fast chopper 31 is switched ON and OFF in a predetermined frequency. Lock-in amplifier 38 captures signals according to the predetermined frequency and filters out noise. To measure V-T plots, a reflective tube 39 may be placed between the fast chopper 31 and the light source 30. A bandpass filter 35 may be provided between device under test 32 and light source 30. The distance between device under test 32 and light source 30 could be 10 cm. The electrical signal generated by device under test 32 pass through lock-in amplifier 38 first, then received by power meter 33 (Keithley 2400), and finally transmitted to computer 34. The measurement system is usually covered by a box to prevent light leakage.

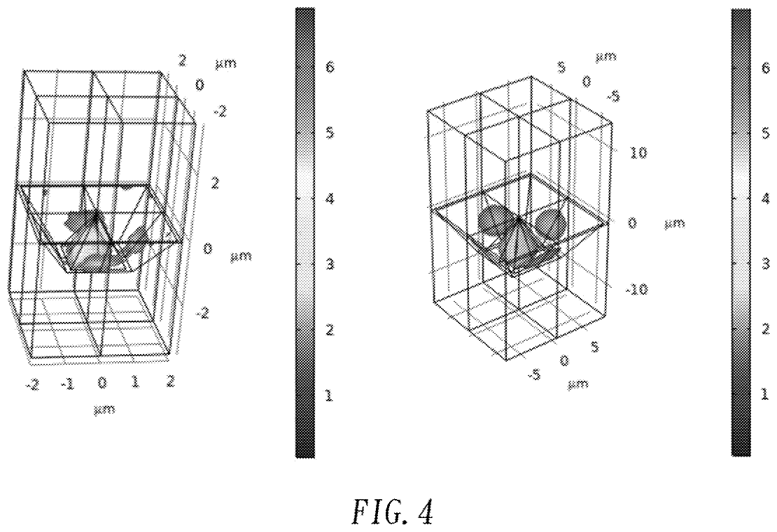

FIG. 4 shows light field simulation of the photodetector 1 shown in FIG. 1. The fabricated W-shaped composite pyramid structure combines an inverted trapezoidal cavity and an upright pyramid. The upright pyramid concentrates on the electric field and enhances resonance. Light field simulations show that the W-shaped composite pyramid structure effectively enhances electrical filed and resonance within the cavity.

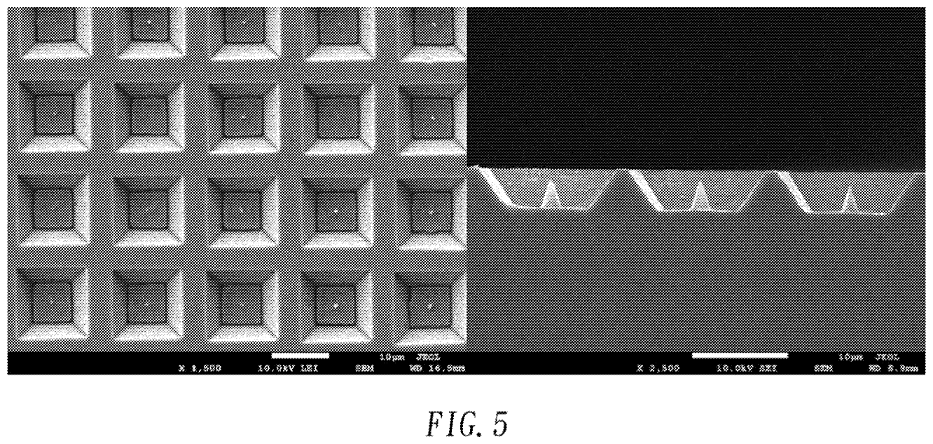

FIG. 5 are top-view (1500×) and side-view (2500×) scanning electron microscope (SEM) images of a W-shaped composite pyramid structure array fabricated according to an embodiment of the present invention. The SEM images reveal that the W-shaped composite structure contains an upright pyramid protruded from central bottom region of the trapezoidal cavity.

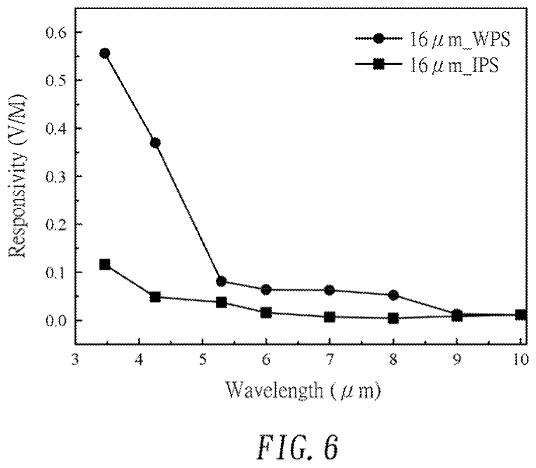

FIG. 6 shows relationship between incident light wavelength and responsivity of an inventive photodetector with a W-shaped composite structure array formed on silicon surface with a period of 16 μm and a comparison photodetector with an inverted pyramid structure (IPS) array formed on silicon surface with a period of 16 μm. In the infrared band, the photodetector with W-shaped composite structure array exhibits a significantly improved responsivity compared to photodetector with IPS array. For example, at wavelength of 3.46 μm, the responsivity of WPS photodetector is approximately 4.72 times higher than that of IPS photodetector.

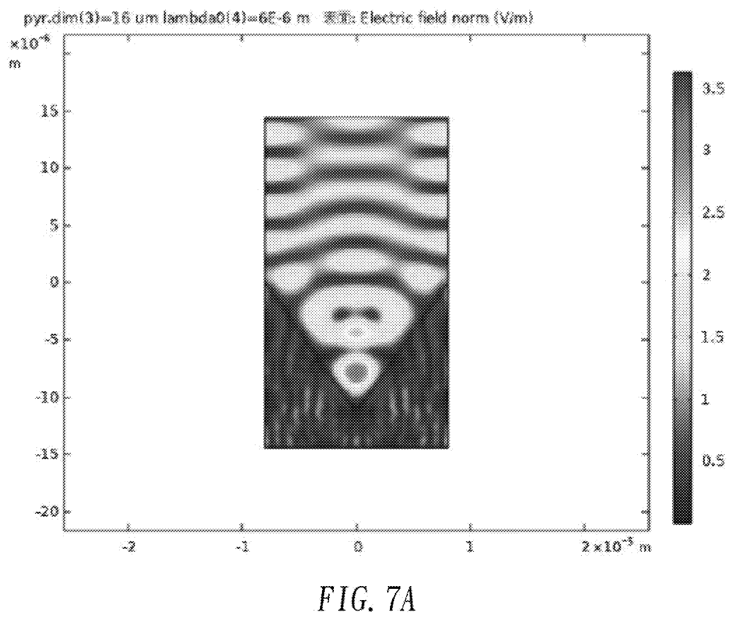

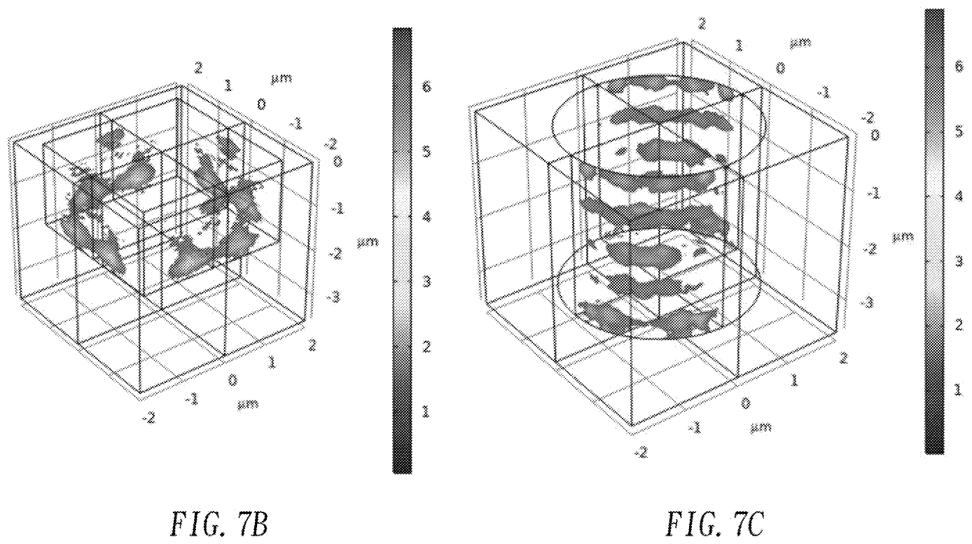

FIGS. 7A, 7B, and 7C are light field simulations of composite structures respectively having only inverted pyramid, cubic, and cylindrical resonant cavities according to some embodiments of the present invention.

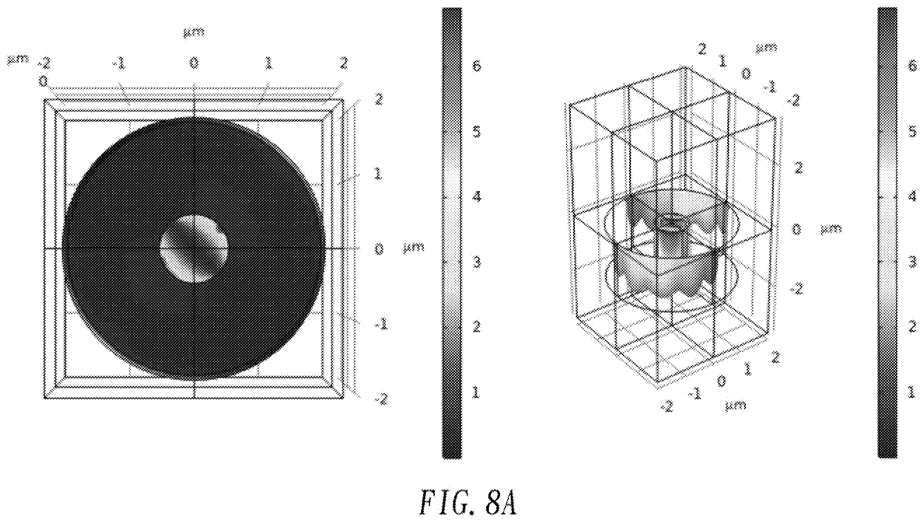

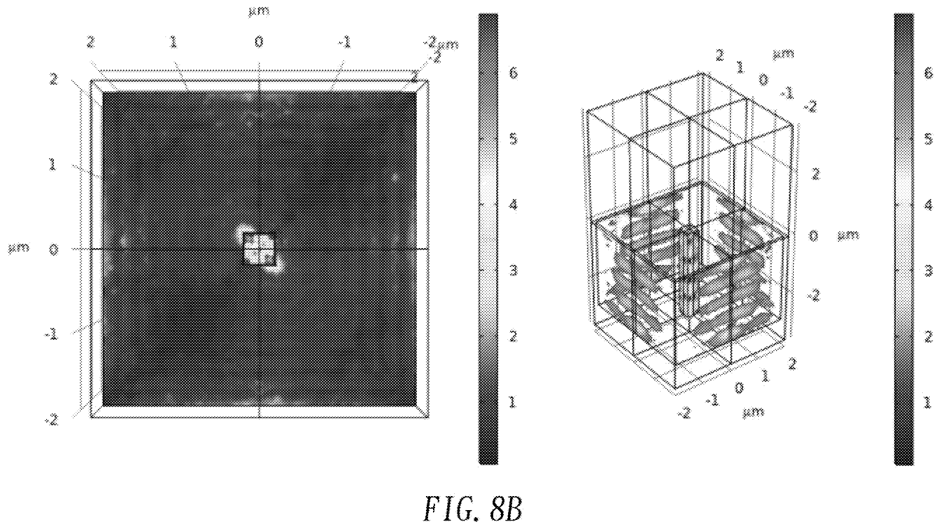

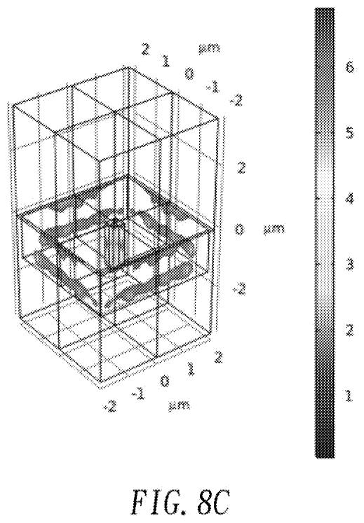

FIG. 8A shows light field simulation of a composite structure including a cylindrical resonant cavity and a cylindrical center core structure in accordance with an embodiment of the present invention.

FIG. 8B shows light field simulation of a composite structure including a cubic resonant cavity and a cubic center core structure in accordance with an embodiment of the present invention.

FIG. 8C shows light field simulation of a composite structure including a cubic resonant cavity and a cubic center core structure in accordance with an embodiment of the present invention, wherein the height of the cubic center core structure is greater than the height of the cubic resonant cavity.

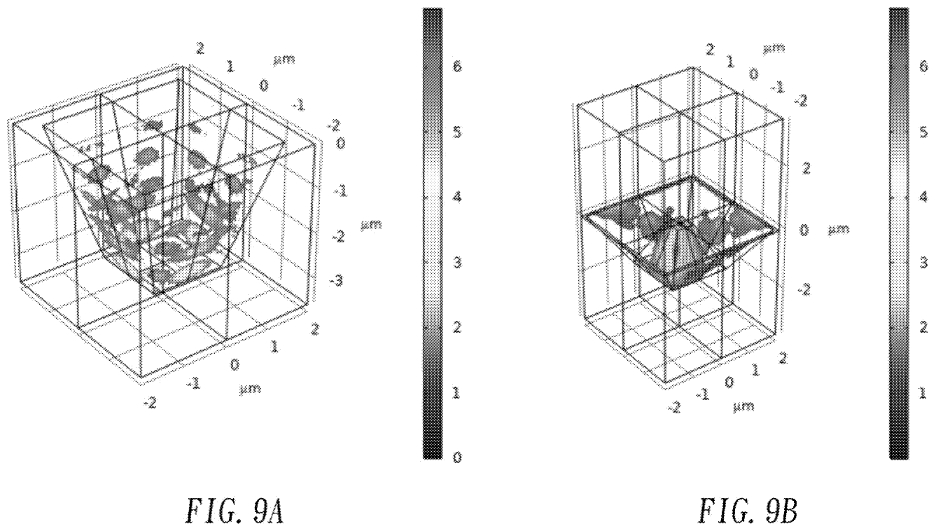

FIG. 9A shows light field simulation of a composite structure having only an inverted trapezoid cavity in accordance with an embodiment of the present invention.

FIG. 9B shows light field simulation of a composite structure having an inverted trapezoidal resonant cavity and a trapezoidal center core structure in accordance with an embodiment of the present invention.

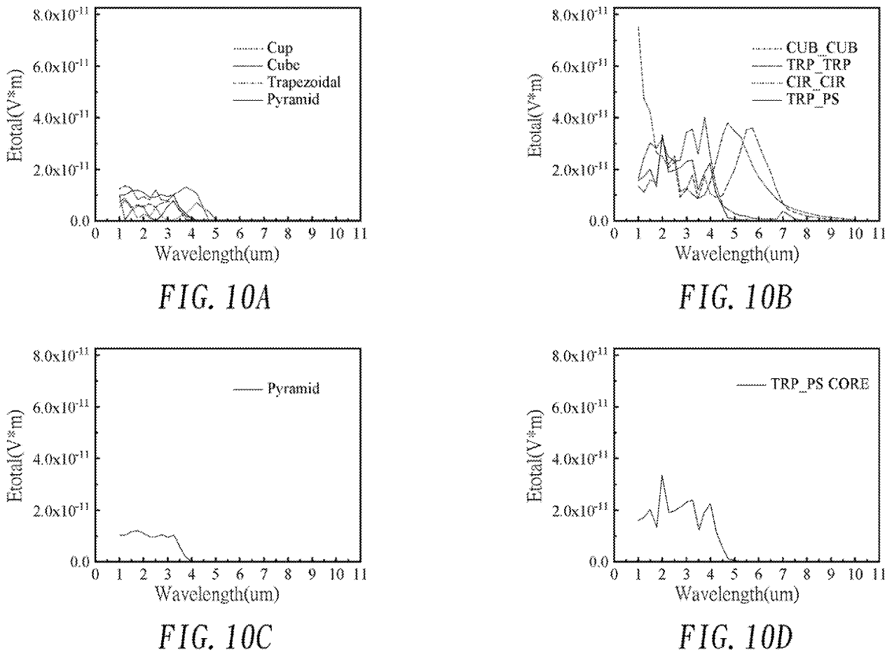

FIG. 10A shows line graphs of incident light wavelength versus integrated electric field for composite structure containing only cup-shaped, cube-shaped, trapezoidal, and inverted pyramid resonant cavity.

FIG. 10B shows line graphs of incident light wavelength versus integrated electric field for composite structure containing cube-shaped resonant cavity and cube-shaped central core structures (CUB_CUB), inverted trapezoidal resonant cavity and trapezoidal central core structures (TRP_TRP), cylindrical resonant cavity and cylindrical central core structures (CIR_CIR), and inverted trapezoidal resonant cavity and upright pyramid central core structures (TRP_PS), respectively. As shown in FIG. 10B, the (CUB_CUB) composite structure has the strongest resonant electric field for incident light with wavelengths of approximately 5.5 μm to 6 μm, the (TRP_TRP) composite structure has the strongest resonant electric field for incident light with wavelengths of approximately 4 μm, and the (CIR_CIR) composite structure has the strongest resonant electric field for incident light with wavelengths of approximately 4.5 μm to 5 μm.

FIG. 10C shows a line graph of incident light wavelength versus integrated electric field for composite structure containing only inverted pyramid resonant cavity.

FIG. 10D shows a line graph of incident light wavelength and integrated electric field for composite structure containing an inverted trapezoidal resonant cavity and an upright pyramidal central core structure. As shown in FIG. 10D, the (TRP_PS) composite structure exhibits the strongest resonant electric field for incident light with wavelengths of approximately 2 μm and 3 μm to 4 μm. The results demonstrate that photodetectors with different composite structures can be fabricated for different detected wavelength bands.

Although exemplary photodetectors use specific materials, other materials such as those described in TW Pat. Nos. TWI686936B and TWI806274B can be used. For example, the metal layer may be made of gold, silver, copper, chromium, nickel, or combinations thereof. In some embodiments, a detection device with a photodetector array comprising one or more photodetectors described herein is provided. The detection device can be referred to as Taiwan Pat. No. TWI 897815B, filed on Feb. 26, 2025, the entire contents of which are fully incorporated by reference as if fully set forth herein. In some embodiments, the detection device is a thermal imaging device.

In some embodiments, the detection device is used to detect one or more target gases. The detection device further includes a gas chamber in which the one or more target gases are disposed. The light passes through the one or more target gases and then is received by the photodetector array to be converted into an electrical signal.

In one embodiment, the light source emits a light with wavelengths covering near-infrared (NIR) to mid-wave infrared (MWIR), and the detection device further includes one or more reflectors and/or lenses and a filter array. The light is reflected or passes through by the one or more reflector and/or lenses arranged in the gas chamber, then passes through the filter array, and then is received by the photodetector array to be converted into an electrical signal.

In one embodiment, the light source emits a light with wavelengths covering near-infrared (NIR) to mid-wave infrared (MWIR), and the detection device further includes a beam splitter. The light passes through the beam splitter arranged in the gas chamber and then is received by the photodetector array to be converted into an electrical signal.

In one embodiment, the light source emits a plurality of narrowband monochromatic beams of different wavelengths. These monochromatic beams pass through the one or more target gases and are received by the photodetector array to be converted into electrical signal.

In one embodiment, the gas chamber includes a plurality of gas channels that are gas-interconnected and optically non-interfering with one another. Each gas channel contains one or more target gases. The monochromatic beams pass through corresponding one of the gas channels and are received by one or more corresponding photodetectors in the photodetector array to be converted into electrical signals.

Unless otherwise indicated, all number or expressions, such as those expressing dimensions, physical characteristics, etc., used in the specification (other than the claims) are understood as modified in all instances by the term “approximately”. At the very least, and not as an attempt to limit the application of the doctrine of equivalents to the claims, each numerical parameter recited in the specification or claims which is modified by the term “approximately” should at least be construed in light of the number of recited significant digits and by applying rounding techniques.

Although the technology has been described in language that is specific to certain structures and materials, it is to be understood that the invention defined in the appended claims is not necessarily limited to the specific structures and materials described. Rather, the specific aspects are described as forms of implementing the claimed invention. Because many embodiments of the invention can be practiced without departing from the spirit and scope of the invention, the invention resides in the claims hereinafter appended.

What is claimed is:

1. A photodetector, comprising:
a semiconductor substrate having a composite structure array composed of a plurality of composite structures;
a metal layer forming a Schottky contact with a surface of the composite structure array;
a first electrode in contact with an upper surface of the metal layer;
a second electrode in an ohmic contact with a lower surface of the semiconductor substrate;
wherein each of the plurality of composite structures comprises a resonant cavity allowing for an incident light inducing resonance therein and a center core structure protruded from a central bottom of the resonant cavity for collecting resonant energy.

2. The photodetector according to claim 1, wherein the resonant cavity is inverted pyramid-shaped, inverted trapezoid-shaped, cuboid-shaped, or cup-shaped.

3. The photodetector according to claim 1, wherein the center core structure is upright pyramid-shaped, cylinder-shaped, cuboid-shaped, trapezoid-shaped, or cone-shaped.

4. The photodetector according to claim 1, wherein the photodetector is used to detect the incident light with wavelengths greater than 1.1 um.

5. The photodetector according to claim 1, wherein a responsivity of the photodetector is equal to or greater than 0.557 V/W for the incident light at wavelength of 3.46 μm.

6. The photodetector according to claim 1, wherein the first electrode is fence-shaped.

7. The photodetector according to claim 1, wherein the first electrode is mesh-shaped.

8. The photodetector according to claim 1, wherein the metal layer is conformally deposited on the surface of the composite structure array.

9. The photodetector according to claim 1, wherein a thickness of the metal layer is approximately 10 nm.

10. A method for fabricating a photodetector, comprising:
providing a semiconductor substrate;
depositing a shielding layer on an upper surface of the semiconductor substrate;
depositing a photoresist layer over the shielding layer that is deposited on the upper surface of the semiconductor substrate;
exposing and developing the photoresist layer with a photomask to obtain a patterned photoresist layer, wherein the photomask comprises an array of light-blocking patterns, and wherein each of the light-blocking patterns comprises a light-transmitting core portion, or each of the light-blocking patterns comprises an outer pattern and a light-blocking core pattern within the outer pattern;
etching the shielding layer and the patterned photoresist layer to obtain a patterned shielding layer;
etching the semiconductor substrate to form a composite structure array, wherein the composite structure array comprises a plurality of composite structures, and each of the plurality of composite structures comprises a resonant cavity allowing for an incident light inducing resonance therein and a center core structure protruded from a central bottom of the resonant cavity for collecting resonant energy;
depositing a metal layer on a surface of the plurality of composite structures;
depositing a first electrode on the metal layer; and
depositing a second electrode on a lower surface of the semiconductor substrate.

11. The method according to claim 10, wherein each of the light-blocking patterns comprise a first square pattern and a second square pattern within the first square pattern.

12. The method according to claim 10, wherein the metal layer is conformally formed on the surface of the plurality of composite structures.

13. A detection device for detecting a light emitted from a light source, wherein the detection device comprises a photodetector array that comprises one or more photodetectors according to claim 1.

14. The detection device according to claim 13, wherein the detection device is a thermal imaging device.

15. The detection device according to claim 13, wherein the detection device is used to detect one or more target gases, and the detection device further comprises a gas chamber in which the one or more target gases are disposed, and wherein the light passes through the one or more target gases and then is received by the photodetector array to be converted into an electrical signal.

16. The detection device according to claim 15, wherein wavelengths of the light cover near-infrared (NIR) to mid-wave infrared (MWIR) band, and the detection device further comprises one or more reflectors and/or lenses and a filter array, and wherein the light is reflected or passes through by the one or more reflector and/or lenses arranged in the gas chamber, then passes through the filter array, and then is received by the photodetector array to be converted into an electrical signal.

17. The detection device according to claim 15, wherein wavelengths of the light cover near-infrared (NIR) to mid-wave infrared (MWIR) band, and the detection device further comprises a beam splitter, and wherein the light passes through the beam splitter arranged in the gas chamber and then is received by the photodetector array to be converted into an electrical signal.

18. The detection device according to claim 15, wherein the light comprises a plurality of narrowband monochromatic beams of different wavelengths, and the plurality of narrowband monochromatic beams pass through the one or more target gases and are received by the photodetector array to be converted into electrical signal.

19. The detection device according to claim 18, wherein the gas chamber comprises a plurality of gas channels that are gas-interconnected and optically non-interfering with one another, and each of the plurality of gas channels contains the one or more target gases, and wherein the plurality of narrowband monochromatic beams pass through corresponding one of the plurality of gas channels and are received by one or more corresponding photodetectors in the photodetector array to be converted into electrical signals.
